(19) United States
(12) Patent Application Publication
(10) Pub. No.: US 2020/0187386 A1
(43) Pub. Date: Jun. 11, 2020

(54) THERMAL INTERFACE ASSEMBLY

(71) Applicant: ZF ACTIVE SAFETY AND ELECTRONICS US LLC, Livonia, MI (US)

(72) Inventor: DARRYL J. EDWARDS, Novi, MI (US)

(21) Appl. No.: 16/214,249

(22) Filed: Dec. 10, 2018

(51) Int. Cl. H05K 7/20; F28F 13/00; F28F 21/06

(52) U.S. Cl. CPC H05K 7/20454; F28F 13/00; F28F 21/067; F28F 2255/02; F28F 2013/001; F28F 2013/006; H05K 7/20481

(57) ABSTRACT

A thermal interface assembly for transferring heat from a heat generating component to a heat dissipating component. The thermal interface assembly includes a one-piece thermal sheet having a plurality of arms.

### FIELD OF THE INVENTION

The present invention relates to the assembly of electronics and, in particular, to a thermal interface assembly that can be used to secure a heat generating component to a heat dissipating component.

### BACKGROUND TO THE INVENTION

It is known to use thermal interface material to attach a heat dissipating component to a heat generating component in electronic devices. The thermal interface material promotes the transfer of heat from the heat generating component to the heat dissipating component. Thermal interface materials may be stiff due to the addition of thermal conductivity enhancing fillers. The stiffness of the thermal interface materials can result in the application of high compressive forces during assembly of electronic devices. However, such high compressive forces are undesirable, as they can cause damage to, among other components, the heat generating component, joint(s) used to attach the heat generating component to a circuit board, the circuit board itself, solder joint(s), and/or the heat dissipating component. It has been suggested to decrease the stiffness of the thermal interface material (i.e., increase flexibility) by reducing the use of thermal conductivity enhancing fillers. However, this reduction of thermal conductivity enhancing fillers decreases thermal conductivity. Thus, what is desired is an assembly that is soft, flexible, and has good thermal conductivity.

One solution has been to provide an assembly 100 (FIG. 1) that includes a thermal sheet 106 attached to a resilient pad 103 by an adhesive 151. The assembly 100 can be used to transfer heat from a heat generating component to a heat dissipating component. However, it is desired to improve heat transfer from heat generating components to heat dissipating components, as heat transfer along the in-plane path of the known assembly 100 is relatively long.

### SUMMARY OF THE INVENTION

According to one aspect of the invention, a thermal interface assembly for connecting a heat dissipating component to a heat generating component includes a resilient pad having a first surface and a second opposite surface. A one-piece thermal sheet is configured to transfer heat from the heat generating component to the heat dissipating component along an in-plane path. The thermal sheet has a first surface and a second opposite surface. The thermal sheet includes a main portion and a plurality of arms extending from a respect one of a plurality of sides of the main portion. The thermal sheet is attached to the pad such that the first surface of the thermal sheet faces toward the pad and the second surface of the thermal sheet faces away from the pad.

### BRIEF DESCRIPTION OF THE DRAWINGS

Embodiments of the invention will now be described by way of example only, with reference to the accompanying drawings, in which:

FIG. 1 is a perspective view of a known thermal assembly;

FIG. 2 is a perspective view of a thermal interface assembly according to one embodiment of the invention;

FIG. 3 is another perspective view of the thermal interface assembly of FIG. 2;

FIG. 4 is a perspective view of a pad that makes up part of the thermal interface assembly of FIG. 2;

FIG. 5 is a plan view of a thermal sheet that makes up part of the thermal assembly of FIG. 2;

FIG. 6 is another plan view of the thermal sheet of FIG. 5;

FIG. 7 is sectional view along 7-7 of FIG. 2;

FIG. 8 is a sectional view along 8-8 of FIG. 2;

FIG. 9 is a perspective view of a partially assembled thermal interface assembly of FIG. 2;

FIG. 10 is a perspective view of a further partially assembled thermal interface assembly of FIG. 2; and

FIG. 11 is a sectional view of the thermal interface assembly of FIG. 2 showing the thermal interface assembly between a heat generating component and a heat dissipating component.

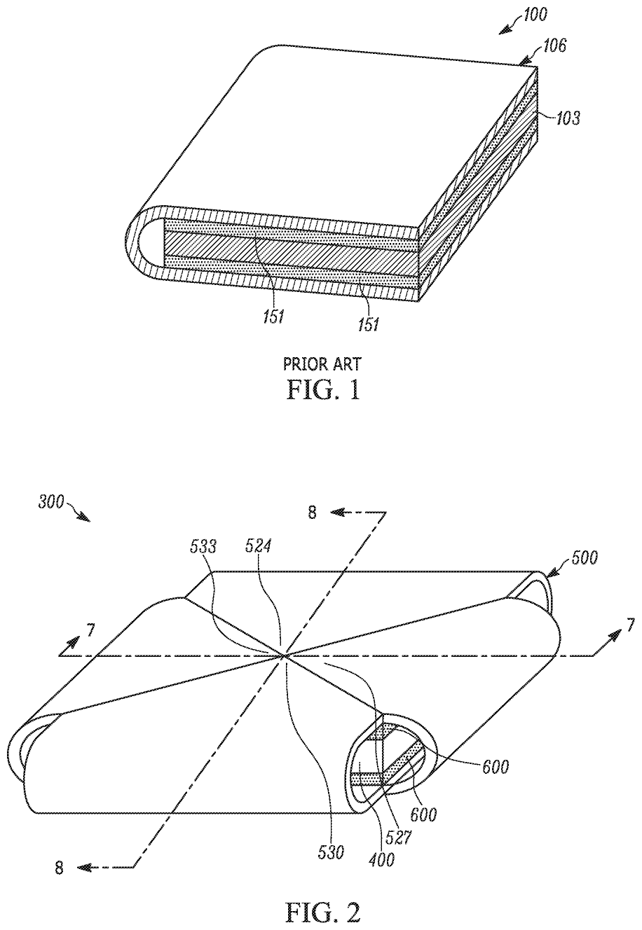

### DETAILED DESCRIPTION

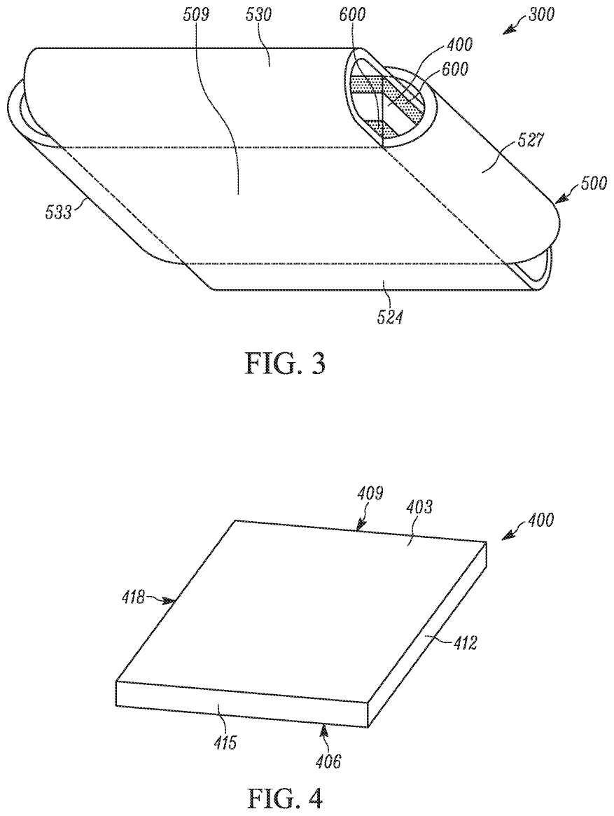

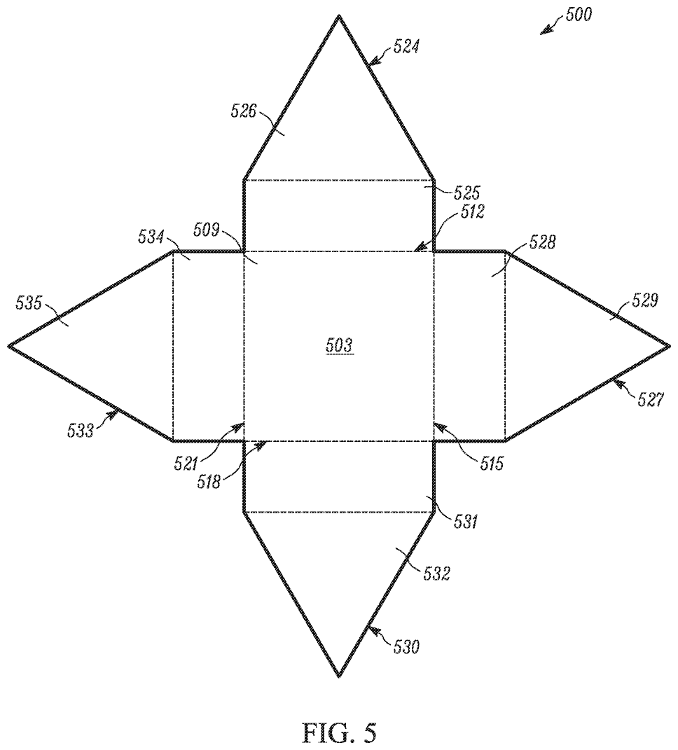

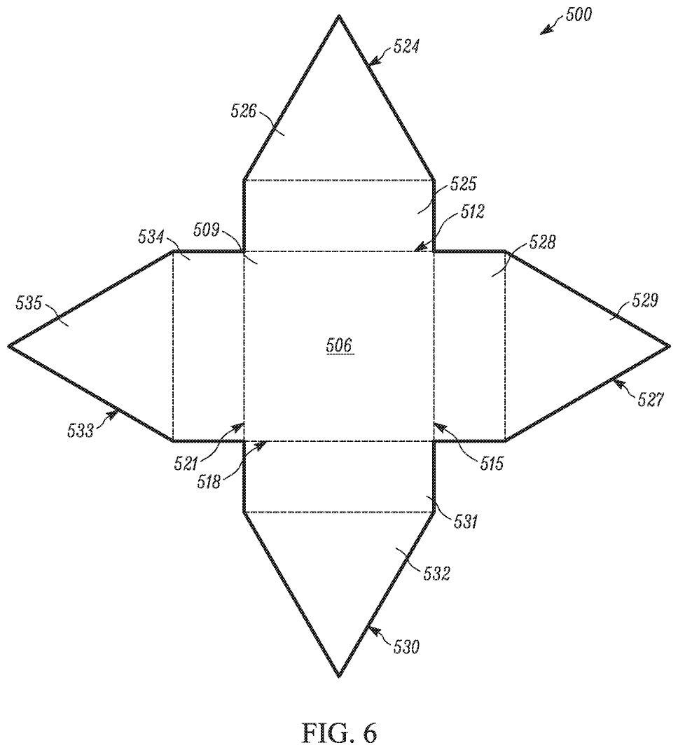

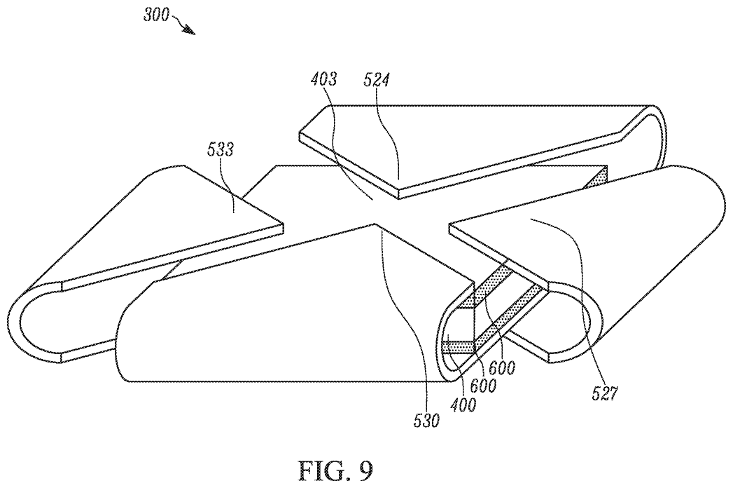

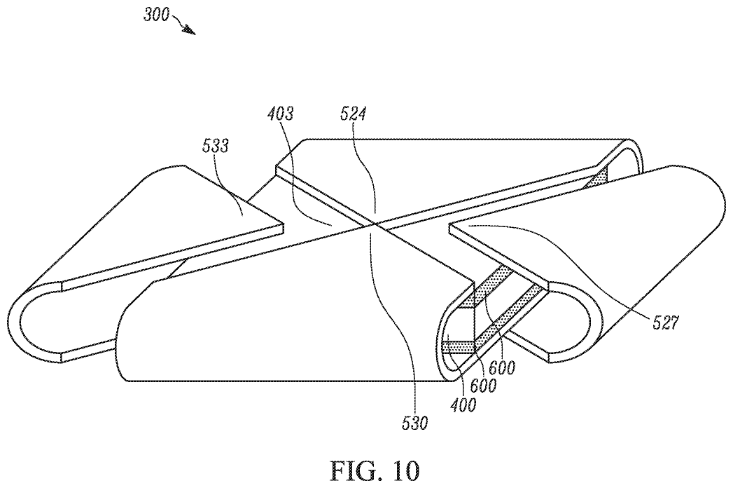

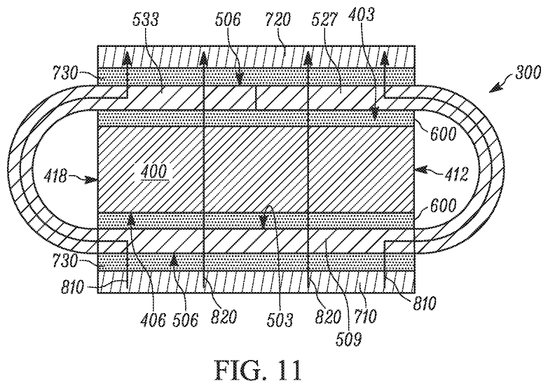

An exemplarily thermal interface assembly 300 is shown in FIGS. 2, 3, and 7-10. The thermal interface assembly 300 includes a resilient pad 400 (FIG. 4) and a one-piece thermal sheet 500 (FIGS. 5 and 6). The resilient pad 400 can be manufactured out of any soft material (e.g., open cell or closed cell foam or soft thermal pad material). The thermal sheet 500 can be manufactured out of any material having high heat conductivity and that is bendable/flexible (e.g., pyrolytic graphite sheet, graphene, carbon fiber sheet, copper, aluminum).

The resilient pad 400 (FIG. 4) includes a first surface 403 and a second surface 406. The first and second surfaces 403, 406 are bound by a plurality of sides 409, 412, 415, 418. In one example, the resilient pad 400 includes four sides 409, 412, 415, 418 that are arranged to give the resilient pad 400 a square shape when the resilient pad 400 is viewed in plan view. However, the resilient pad 400 can have any desired number of sides that are arranged to give the resilient pad any desired shape.

The one-piece thermal sheet 500 includes a pad facing surface 503 (FIG. 5) and an opposite component facing surface 506 (FIG. 6). The thermal sheet 500 further includes a main portion 509 having a plurality of sides 512, 515, 518, 521 and one of a plurality of arms 524, 527, 530, 533 extending from a respective side. In one example, the main portion 509 of the thermal sheet 500 has four sides 512, 515, 518, 521 and the thermal sheet 500 has four arms 524, 527, 530, 533 that are arranged to give the thermal sheet 500 a cruciform shape when the thermal sheet 500 is viewed in plan view. However, the main portion 509 of the thermal sheet 500 can have any number of desired sides and the thermal sheet 500 can have any number of desired arms that are arranged to give the thermal sheet 500 any desired shape.

The first arm 524 includes a straight portion 525 and a tapered portion 526. The straight portion 525 spaces the tapered portion 526 from the first side 512 of the main portion 509. It is contemplated that a length of the straight portion 525 can be selected to accommodate a minimum bend radius of the material used to manufacture the thermal sheet 500. The straight portion 525 has a constant width along a length of the first arm 524. The tapered portion 526 has a width that decreases along the length of the first arm 524 in a direction extending away from the first side 512 of the main portion 509.

The second arm 527 includes a straight portion 528 and a tapered portion 529. The straight portion 528 spaces the tapered portion 529 from the second side 515 of the main portion 509. It is contemplated that a length of the straight portion 528 can be selected to accommodate a minimum bend radius of the material used to manufacture the thermal sheet 500. The straight portion 528 has a constant width along a length of the second arm 527. The tapered portion 529 has a width that decreases along the length of the second arm 527 in a direction extending away from the second side 515 of the main portion 509.

The third arm 530 includes a straight portion 531 and a tapered portion 532. The straight portion 531 spaces the tapered portion 532 from the third side 518 of the main portion 509. It is contemplated that a length of the straight portion 531 can be selected to accommodate a minimum bend radius of the material used to manufacture the thermal sheet 500. The straight portion 531 has a constant width along a length of the third arm 530. The tapered portion 532 has a width that decreases along the length of the third arm 530 in a direction extending away from the third side 518 of the main portion 509.

The fourth arm 533 includes a straight portion 534 and a tapered portion 535. The straight portion 534 spaces the tapered portion 535 from the fourth side 521 of the main portion 509. It is contemplated that a length of the straight portion 534 can be selected to accommodate a minimum bend radius of the material used to manufacture the thermal sheet 500. The straight portion 534 has a constant width along a length of the fourth arm 533. The tapered portion 535 has a width that decreases along the length of the fourth arm 533 along a direction extending away from the fourth side 521 of the main portion 509.

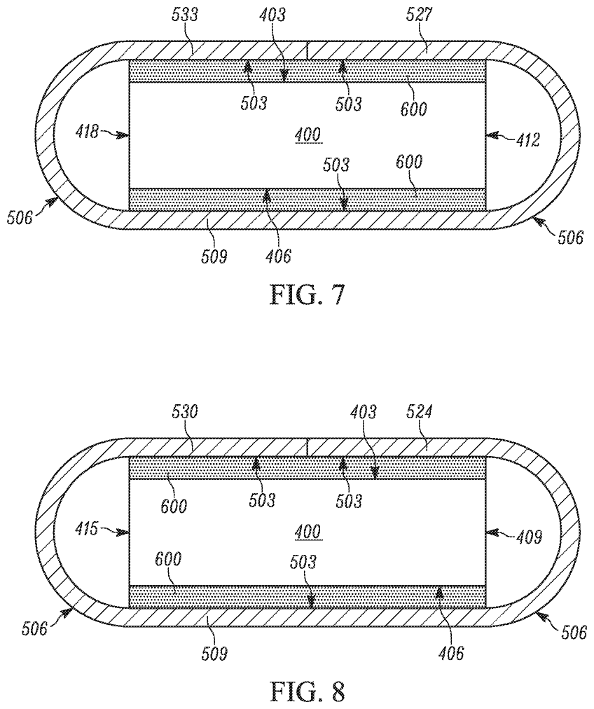

The thermal sheet 500 is attached to the resilient pad 400 by an adhesive 600. The adhesive 600 can be applied to the resilient pad 400 and/or the thermal sheet 500. It is contemplated that any other suitable mechanism or arrangement can be used to attach the thermal sheet 500 to the resilient pad 400. At least a part of the pad facing surface 503 of the main portion 509 of the thermal sheet 500 is secured to the second surface 406 of the resilient pad 400 and at least a part of the pad facing surface 503 of each of the four arms 524, 527, 530, 533 of the thermal sheet 500 is secured to the first surface 403 of the resilient pad 400 (FIGS. 7 and 8). The tapered portions 526, 529, 532, 535 of each of the four arms 524, 527, 530, 533 of the thermal sheet 500 substantially abut one another on a middle portion of the first surface 403 of the resilient pad 400 (i.e., halfway between the first side 409 and the third side 415 and halfway between the second side 412 and the fourth side 418).

With the thermal sheet 500 attached to the resilient pad 400 in the foregoing manner, the first arm 524 of the thermal sheet 500 curves about the first side 409 of the resilient pad 400, the second arm 527 of the thermal sheet 500 curves about the second side 412 of the resilient pad 400, the third arm 530 of the thermal sheet 500 curves about the third side 415 of the resilient pad 400, and the fourth arm 533 of the thermal sheet 500 curves about the fourth side 418 of the resilient pad 400. As set forth above, the length of the straight portion 525, 528, 531, 534 of each respective arm 524, 527, 530, 533 can be selected to ensure that the curves accommodate a minimum bend radius of the material used to manufacture the thermal sheet 500. The entire pad facing surface 503 faces toward the resilient pad 400 and the entire component facing surface 506 faces away from the resilient pad 400.

The thermal interface assembly 300 can be disposed between a heat generating component 710 and a heat dissipating component 720 (FIG. 11). Adhesive 730 can be applied to at least a part of the component facing surface 506 to secure the heat generating component 710 to at least a part of the main portion 509 of the thermal sheet 500 and to secure the heat dissipating component 720 to at least a part of at least one arm of the four arms 524, 527, 530, 533 of the thermal sheet 500. In this arrangement, the first surface 403 of the resilient pad 400 faces the heat dissipating component 720 and the second surface 406 of the resilient pad 400 faces the heat generating component 710.

The heat dissipating component 720 is provided to dissipate heat generated by the heat generating component 710. The thermal interface assembly 300 is configured to promote heat transfer from the heat generating component 710 to the heat dissipating component 720. Heat moving through the thermal interface assembly 300 moves along an in-plane path 810 and a through-plane path 820. As indicated by the arrows, heat moving along the in-plane path 810 remains in the thermal sheet 500 as the heat moves from the heat generating component 710 to the heat dissipating component 720. As further indicated by the arrows, heat moving along the through-plane path 820 does not remain in the thermal sheet 500 and, instead, radiates through the thermal sheet 500 and the resilient pad 400. Due to the chemical structure of the thermal sheet 500 and the overall construction of the thermal interface assembly 300, the in-plane path 810 is the primary means of transferring heat from the heat generating component 710 to the heat dissipating component 720.

The multiple arms 524, 527, 530, 533 of the thermal sheet 500 of the thermal interface assembly 300 provides multiple, short, in-plane paths 810 that improve heat transfer from the heat generating component 710 to the heat dissipating component 720. Furthermore, the unitary design of the thermal sheet 500 facilitates economic and efficient manufacture of the thermal interface assembly.

What have been described above are examples of the disclosure. It is, of course, not possible to describe every conceivable combination of components or method for purposes of describing the disclosure, but one of ordinary skill in the art will recognize that many further combinations and permutations of the disclosure are possible. Accordingly, the disclosure is intended to embrace all such alterations, modifications, and variations that fall within the scope of this application, including the appended claims.

1. A thermal interface assembly for connecting a heat dissipating component to a heat generating component, the thermal interface assembly comprising:
a resilient pad having a first surface and a second opposite surface; and
a one-piece thermal sheet configured to transfer heat from the heat generating component to the heat dissipating component along an in-plane path, the one-piece thermal sheet having a first surface and a second opposite surface, the one-piece thermal sheet including a main portion and a plurality of arms extending from a respective one of a plurality of sides of the main portion, the one-piece thermal sheet being attached to the resilient pad such that the first surface of the one-piece thermal sheet faces toward the resilient pad, the second surface of the one-piece thermal sheet faces away from the resilient pad, and the resilient pad is positioned between the main portion and the plurality of arms.

2. The thermal interface assembly of claim 1, wherein each one of the plurality of arms has a straight portion and a tapered portion.

3. The thermal interface assembly of claim 2, wherein the straight portion spaces the tapered portion from the main portion.

4. The thermal interface assembly of claim 2, wherein the tapered portion of each one of the plurality of arms abut one another.

5. The thermal interface assembly of claim 4, wherein the tapered portion of each of the plurality of arms abut one another on a middle portion of the first surface of the resilient pad.

6. The thermal interface assembly of claim 1 further comprising an adhesive that attaches the first surface of the one-piece thermal sheet to the resilient pad.

7. The thermal interface assembly of claim 1, wherein the main portion of the one-piece thermal sheet includes four sides.

8. The thermal interface assembly of claim 7, wherein the one-piece thermal sheet includes four arms.

9. The thermal interface assembly of claim 8, wherein the one-piece thermal sheet is substantially cruciform shaped.

10. An electronic assembly comprising:
a thermal interface assembly according to claim 1
the heat generating component attached to the second surface of the one-piece thermal sheet; and
the heat dissipating component attached to the second surface of the one-piece thermal sheet;
wherein the one-piece thermal sheet transfers heat from the heat generating component to the heat dissipating component along the in-plane path.

11. The thermal interface assembly of claim 1, wherein the main portion of the one-piece thermal sheet is connected to the second surface of the resilient pad and the plurality of arms are connected to the first surface of the resilient pad.
